(19) United States
(12) Patent Application Publication
(10) Pub. No.: US 2012/0187545 A1
(43) Pub. Date: Jul. 26, 2012

(54) DIRECT THROUGH VIA WAFER LEVEL FANOUT PACKAGE

(75) Inventors: Rezaur Rahman Khan, Rancho Santa Margarita, CA (US); Edward Law, Ladera Ranch, CA (US); Ken Jian Ming Wang, Milpitas, CA (US)

(73) Assignee: BROADCOM CORPORATION, Irvine, CA (US)

(21) Appl. No.: 13/173,109

(22) Filed: Jun. 30, 2011

Related U.S. Application Data
(60) Provisional application No. 61/435,648, filed on Jan. 24, 2011.

(51) Int. Cl. H01L 23/488; H01L 21/66

(52) U.S. Cl. 257/621; 438/15; 257/E21.529; 257/E23.023

(57) ABSTRACT

Methods, systems, and apparatuses are described for improved integrated circuit packages. An integrated circuit package includes a semiconductor substrate and a semiconductor die. The semiconductor substrate has opposing first and second surfaces, a plurality of vias through the semiconductor substrate, and routing one or both surfaces of the semiconductor substrate. The die is mounted to the first surface of the semiconductor substrate. An encapsulating material encapsulates the die on the first surface of the semiconductor substrate.

This application claims the benefit of U.S. Provisional Application No. 61/435,648, filed on Jan. 24, 2011, which is incorporated by reference herein in its entirety.

### BACKGROUND OF THE INVENTION

1. Field of the Invention

The present invention relates to integrated circuit packages.

2. Background Art

Integrated circuit (IC) chips or dies are typically interfaced with other circuits using a package that can be attached to circuit board. One such type of IC die package is a ball grid array (BGA) package. BGA packages provide for smaller footprints than many other package solutions available today. One type of BGA package has one or more IC dies attached to a first surface of a package substrate, and has an array of solder ball pads located on a second surface of the package substrate. Solder balls are attached to the solder ball pads. The solder balls are reflowed to attach the package to a circuit board.

An advanced type of BGA package is a wafer-level BGA package. Wafer-level BGA packages have several names in industry, including wafer level chip scale packages (WLCSP), among others. In a wafer-level BGA package, the solder balls are mounted directly to the IC die when the IC die has not yet been singulated from its fabrication wafer. As such, wafer-level BGA packages do not include a package substrate. Wafer-level BGA packages can therefore be made very small, with high pin out, relative to other IC package types including traditional BGA packages.

For IC dies used in wafer-level BGA packages, routing is typically formed directly on the dies. The routing is formed on a surface of the dies to route signals of the die pads to locations where the solder balls attach to the die. Fan-in routing and fanout routing are two different types of routing that may be formed on the dies. Fan-in routing is a type of routing that is formed only within the area of each semiconductor die. Fanout routing is a type of routing that extends outside of the areas of the semiconductor dies (over a material provided around the dies).

As such, fanout routing spreads the signals of IC dies over a larger area than just the area of the dies, providing additional space for interconnects (e.g., solder balls) for the resulting integrated circuit packages. However, conventional techniques for forming wafer-level packages that use fanout routing are expensive, and use a relatively large number of assembly steps. As such, integrated circuit package assembly techniques that enable chip scale packages to be fabricated, are less costly, use fewer process steps are desired.

### BRIEF SUMMARY OF THE INVENTION

Methods, systems, and apparatuses are described for forming integrated circuit packages by mounting an integrated circuit die to a semiconductor substrate having multilayer routing and vias formed through the semiconductor substrate, substantially as shown in and/or described herein in connection with at least one of the figures, as set forth more completely in the claims.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIGS. 1 and 2 show cross-sectional views of example conventional wafer level integrated circuit packages.

FIG. 3 shows a cross-sectional side view of an integrated circuit package, according to an example embodiment.

FIG. 4 shows a flowchart providing an example process for assembling integrated circuit packages, according to an embodiment.

FIG. 5 shows a plan view of a first semiconductor wafer, according to an example embodiment.

FIG. 6 shows an optional process for testing substrate regions of a first semiconductor wafer, according to an embodiment.

FIG. 7 shows a plan view of a second semiconductor wafer, according to an example embodiment.

FIG. 8 shows a view of the semiconductor wafer of FIG. 5 having a die attached to each substrate region of the wafer, according to an example embodiment.

FIG. 9 shows a side cross-sectional view of a portion of the semiconductor wafer of FIG. 5, with first and second dies mounted to respective substrate regions, according to an example embodiment.

FIG. 10 shows a side cross-sectional view of the portion of the wafer shown in FIG. 9 with encapsulated dies, according to an example embodiment.

FIG. 11 shows IC packages singulated from the encapsulated wafer of FIG. 10, according to an example embodiment.

FIG. 12 shows a flowchart providing an example process that uses a carrier for assembling integrated circuit packages, according to an embodiment.

FIG. 13 shows a view of a surface of a carrier that has semiconductor interposer substrates attached, according to an example embodiment.

FIG. 14 shows the view of FIG. 13, with dies attached to the semiconductor substrates, according to an example embodiment.

FIG. 15 shows a side cross-sectional view of dies attached to semiconductor substrates on a carrier, according to example embodiments.

FIG. 16 shows a cross-sectional side view of the carrier of FIG. 15 that mounts semiconductor substrates and dies, with an encapsulating material applied to the carrier to encapsulate the semiconductor substrates and dies, according to an example embodiment.

FIG. 17 shows the cross-sectional side view of FIG. 16, where the carrier has been separated from the encapsulating material, semiconductor substrates, and dies to form a molded assembly, according to an example embodiment.

FIG. 18 shows first and second IC packages singulated from the molded assembly of FIG. 17, according to an example embodiment.

FIG. 19 shows a side cross-sectional view of a portion of an IC package having a semiconductor substrate with multiple routing layers, according to an example embodiment.

FIGS. 20-22 show examples of IC packages that include a semiconductor interposer substrate, according to embodiments.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### I. Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### II. Example Embodiments

Integrated circuit (IC) chips or dies are typically interfaced with other circuits using a package that can be attached to circuit board. One such type of IC die package is a ball grid array (BGA) package. BGA packages provide for smaller footprints than many other package solutions available today. One type of BGA package has one or more IC dies attached to a first surface of a package substrate, and has an array of solder ball pads located on a second surface of the package substrate. Solder balls are attached to the solder ball pads. The solder balls are reflowed to attach the package to a circuit board.

An advanced type of BGA package is a wafer-level BGA package. Wafer-level BGA packages have several names in industry, including wafer level chip scale packages (WLCSP), among others. In a wafer-level BGA package, the solder balls are mounted directly to the IC die when the IC die has not yet been singulated from its fabrication wafer. As such, wafer-level BGA packages do not include a package substrate. Wafer-level BGA packages can therefore be made very small, with high pin out, relative to other IC package types including traditional BGA packages.

For instance, FIG. 1 shows a cross-sectional view of an example conventional wafer level integrated circuit package 100. As shown in FIG. 1, package 100 includes a die 106, first and second dielectric layers 102a and 102b, and an array of solder balls 104. Die 106 has a plurality of die terminals on an active surface of die 106 that are I/O pads for signals of die 106. First dielectric layer 102a is formed on the surface of die 106 over the terminals, and second dielectric layer 102b is formed on a surface of first dielectric layer 102a. Solder balls 104 are formed on a second surface of second dielectric layer 102b. Routing in a routing layer between first and second dielectric layers 102a and 102b and vias through first and second dielectric layers 102a and 102b connect terminals of die 106 to solder balls 104. For example, a terminal 112 of die 106 is shown in FIG. 1 as connected to a solder ball 108 by a trace 110 in the routing layer, and a via 114 through second routing layer 102b.

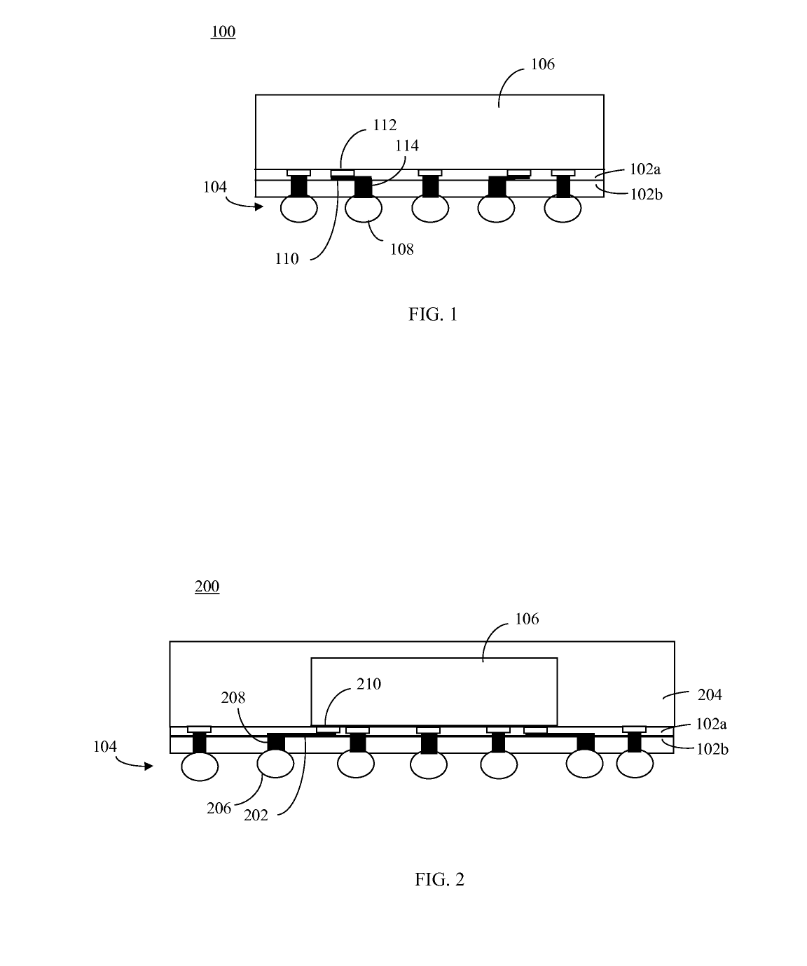

Package 100 of FIG. 1 uses fan-in routing, because routing of the routing layer (e.g., trace 110) is formed only within an area of the bottom surface of die 106 in FIG. 1. FIG. 2 shows a cross-sectional view of an example conventional wafer level integrated circuit package 200 that uses fanout routing. Fanout routing is a type of routing that extends outside of the areas of the semiconductor die (over a material provided around the die). For instance, as shown in FIG. 2, package 200 includes die 106, first and second dielectric layers 102a and 102b, array of solder balls 104, and an insulating material 204. Insulating material 204 surrounds die 106, covering the four perimeter surfaces of die, and a top surface of die in FIG. 2, only not covering the active surface of die 106 where the die terminals are located. Similarly to package 100 of FIG. 1, die 106 has a plurality of die terminals on an active surface of die 106 that are I/O pads for signals of die 106, first dielectric layer 102a is formed on the surface of die 106 over the terminals, second dielectric layer 102b is formed on a surface of first dielectric layer 102a, and solder balls 104 are formed on a second surface of second dielectric layer 102b.

Routing formed in a routing layer between first and second dielectric layers 102a and 102b and vias through first and second dielectric layers 102a and 102b connect terminals of die 106 to solder balls 104. For example, a terminal 210 of die 106 is shown in FIG. 2 as connected to a solder ball 206 by a trace 202 in the routing layer, and a via 208 through second routing layer 102b. Trace 202 is an example of fanout routing, because trace 202 extends outside of an area of the semiconductor die (outside an area of the active surface of die 106) over insulating material 204 provided around die 106. As such, the fanout routing spreads the signals of die 106 over a larger area than just the area of die 106, providing additional space for interconnects (e.g., solder balls 104) for package 200. However, conventional techniques for forming wafer-level packages that use fanout routing, such as package 200 are expensive, and use a relatively large number of assembly steps.

According to embodiments, an active semiconductor device (e.g., die) is attached to a semiconductor interposer substrate that has through-vias, and the semiconductor interposer substrate is used to interface the semiconductor device with a circuit board. The interposer substrate may include a multilayer circuit routing area that provides fanout routing and interconnects with the active semiconductor device. The active semiconductor device and the interposer substrate are encapsulated by an encapsulating material (e.g., a molding compound). Various types of integrated circuit packages that include the active semiconductor device and the semiconductor interposer substrate, including land grid array (LGA) packages, ball grid array (BGA) packages, flip chip LGA packages, flip chip BGA packages, etc. For instance, interconnects (e.g., solder balls) may be attached to a surface of the interposer substrate to form a BGA package.

Embodiments of the present invention overcome limitations of conventional fanout routing packaging. For instance, conventional fanout packaging techniques are limited to single metal layer routing capability, while embodiments having interposer substrates using through vias, such as through silicon vias (TSV), can have multiple routing layers in the interposer substrates.

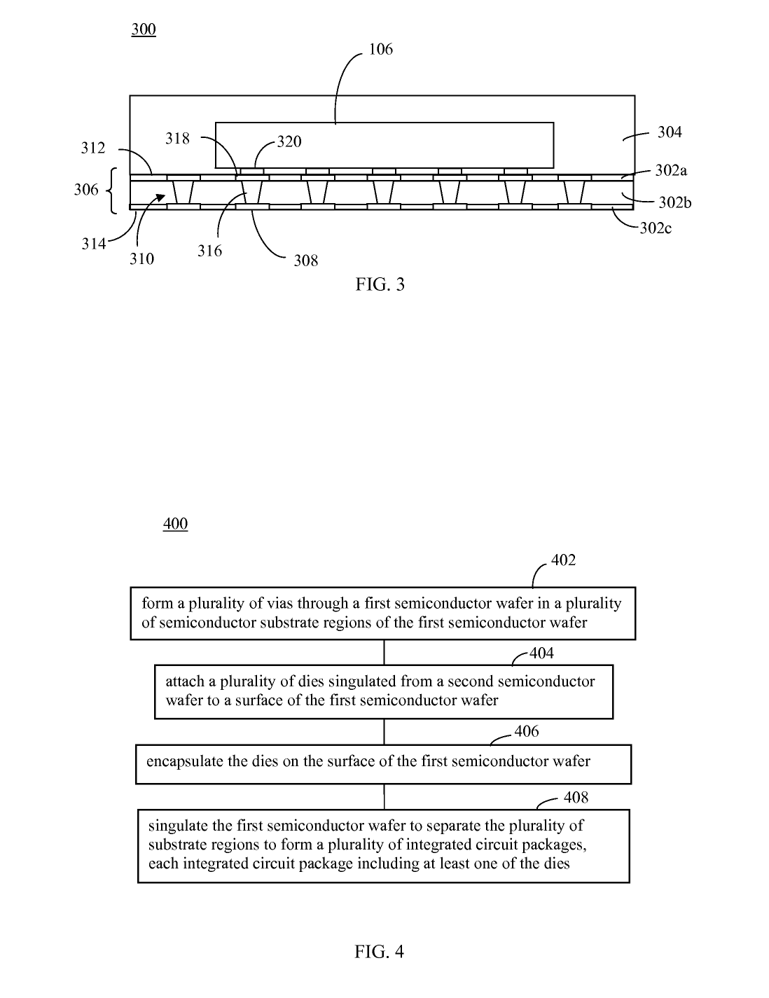

For instance, FIG. 3 shows a cross-sectional side view of an integrated circuit package 300, according to an example embodiment. As shown in FIG. 3, package 300 includes die 106, a semiconductor substrate 306, and an encapsulating material 304. As shown in FIG. 3, semiconductor substrate 306 has opposing first and second surfaces 312 and 314. Semiconductor substrate 306 has a plurality of vias 310 through semiconductor substrate 306. Furthermore, semiconductor substrate 306 includes at least one routing layer. The routing layer may include fanout routing that extends through substrate 306 outside of an area of die 106. Die 106 is mounted to first surface 312 of semiconductor substrate 306. Encapsulating material 304 encapsulates die 106 on first surface 312 of semiconductor substrate 306.

Semiconductor substrate 306 may be made of a semiconductor material, such as silicon or gallium arsenide. For instance, semiconductor substrate 306 may be fabricated in a semiconductor wafer, and singulated from the wafer. Semiconductor substrate 306 may be active (e.g., containing active integrated circuit logic), or may be passive (not containing logic). As shown in FIG. 3, semiconductor substrate 306 may include a core semiconductor layer 302b made of a semiconductor material that is coated on first surface 312 with a first insulating later 302a (e.g., a passivation layer or solder mask layer) and is coated on second surface 314 with a second insulating layer 302c (e.g., a passivation layer or solder mask layer). A first routing layer is formed on first surface 312 of core semiconductor layer 302b that includes electrically conductive features (e.g., traces, via pads, etc.) that may be covered by first insulating layer 302a, or exposed through openings in first insulating layer 302a. Furthermore, a second routing layer is formed on second surface 314 of core semiconductor layer 302b that includes electrically conductive features (e.g., traces, via pads, etc.) that may be covered by second insulating layer 302c, or exposed through openings in second insulating layer 302c. First and second insulating layers 302a and 302c and any number of routing layers may be formed on core semiconductor layer 302b while in wafer form according to standard semiconductor fabrication/processing techniques (e.g., using photolithography, etc.). Routing (e.g., traces) and other electrically conductive features (e.g., via pads, solder ball pads, etc.) of the routing layers described herein may be made of an electrically conductive material, such as a metal or combination of metals/alloy, including copper, aluminum, tin, nickel, gold, silver, a solder, etc.

Vias 310 may be formed through semiconductor substrate 306 while in-wafer. For instance, as shown in FIG. 3, vias 310 may be formed completely through core semiconductor layer 302b. When semiconductor substrate 306 is a silicon substrate (e.g., formed in a silicon wafer), vias 310 may be referred to as through-silicon vias (TSVs).

Vias 310 may be filled or coated with an electrically conductive material (e.g., a metal or combination of metals/alloy, including copper, aluminum, tin, nickel, gold, silver, a solder, etc.). As shown in FIG. 3, vias 310 include a via 316. Via 316 includes a first via pad 318 formed in the first routing layer at first surface 312 of semiconductor substrate 306, and a second via pad 308 formed in the second routing layer at second surface 314 of semiconductor substrate 306. Via 316 forms an electrical connection for a terminal 320 of die 106 through substrate 306. Terminals 320 are access points (e.g., also known as “die pads”, “I/O pads”, etc.) for electrical signals (e.g., input-output signals, power signals, ground signals, test signals, etc.) of die 106. Any number of terminals 320 may be present on the surface of die 106, including 10s, 100s, and even larger numbers of terminals 320.

As shown in FIG. 3, terminal 320 is connected to via pad 308 (e.g., by an electrically conductive adhesive material). As such, terminal 320 is electrically connected through via pad 318 and via 316 to via pad 308 at second surface 314 of substrate 306. When package 300 is mounted to a circuit board, via pad 308 may be directly or indirectly (e.g., through a solder ball) connected to a land pad of the circuit board to electrically couple a signal of terminal 320 to the land pad of the circuit board. Additional terminals of die 106 may be electrically coupled to land pads of a circuit board in a similar fashion.

Package 300 of FIG. 3, and further package embodiments of the present invention, may be formed in various ways. For example the next subsection describes a process for forming integrated circuit packages with semiconductor substrates without the use of an intermediate carrier, followed by a subsection that describes a process for forming integrated circuit packages having semiconductor substrates using of an intermediate carrier. A subsequent subsection is provided that describes various examples of semiconductor interposer substrate routing and examples of IC packages having semiconductor interposer substrates. It noted the embodiments described herein may be combined in any manner, as would be understood by persons skilled in the relevant art(s) from the teachings herein.

### A. Embodiments for Forming Packages without Using a Carrier

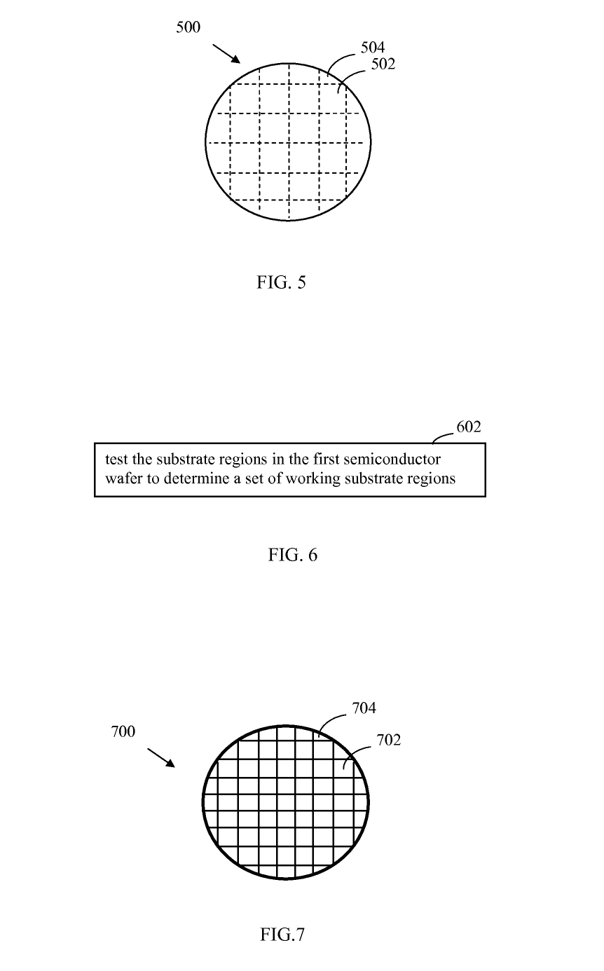

Integrated circuit packages that include a semiconductor interposer substrate, such as package 300 of FIG. 3, may be formed in various ways. For instance, FIG. 4 shows a flowchart 400 providing an example process for assembling integrated circuit packages, according to an embodiment. Flowchart 400 is described with respect to FIGS. 5-11 for purposes of illustration. Other structural and operational embodiments will be apparent to persons skilled in the relevant art(s) based on the discussion provided herein. Flowchart 400 is described as follows.

Referring to flowchart 400, in step 402, a plurality of vias is formed through a first semiconductor wafer in a plurality of semiconductor substrate regions of the first semiconductor wafer. For instance, FIG. 5 shows a plan view of a first semiconductor wafer 500, according to an example embodiment. Wafer 500 may be a silicon wafer, a gallium arsenide wafer, or other wafer type. As shown in FIG. 5, wafer 500 has a surface 504 defined by a plurality of semiconductor substrate regions 502 (shown as dotted rectangles in FIG. 5). Each semiconductor substrate region 502 is configured to be packaged separately into a separate IC package according to the process of flowchart 400. Any number of substrate regions 502 may be included in wafer 500, including 10s, 100s, 1000s, and even larger numbers.

According to step 402, a plurality of vias may be formed through wafer 500 in each of regions 502. For instance, each region 502 may include a plurality of vias similar to vias 310 shown in FIG. 3. Each via may be cylindrical in shape, may be tapered as shown in FIG. 3, or may have other shape. Furthermore, each via may be filled and/or plated with an electrically conductive material, and may have via pads formed (e.g., similar to via pads 318 and 308 shown in FIG. 3). Furthermore, one or more routing layers (and optional insulating layers) may be formed on wafer 500 to provide electrically conductive routing to and from the electrically conductive vias through wafer 500 to other electrically conductive features (e.g., conductive land pads for die terminals, solder ball pads, etc.).

Furthermore, FIG. 6 shows an optional step 602 that may be performed in flowchart 400 of FIG. 4, according to an embodiment. In step 602, the substrate regions may be tested in the first semiconductor wafer to determine a set of working substrates. In embodiments, substrate regions 502 may be tested in wafer 500 to determine working substrates (e.g., substrates 306 of FIG. 3 that pass the testing) and non-working substrates (substrates that fail the testing). Any type and number of tests may be performed on substrate regions 502, as would be known to persons skilled in the relevant art(s). For instance, functional tests may be performed (e.g., by applying probes to conductive features of substrate regions 502 to provide test signals and to measure test results), environmental tests may be performed, etc.

In an embodiment, substrate regions 502 in wafer 500 that are determined to be non-working according to step 602 may be marked. For example, an ink, a laser marking, or other type of mark may be applied to the non-working substrates regions to indicate they are non-working. In this manner, any non-working substrates regions can be identified so that they are not further processed/used.

Referring back to FIG. 4, in step 404, a plurality of dies singulated from a second semiconductor wafer is attached to a surface of the first semiconductor wafer. For instance, FIG. 7 shows a plan view of a second semiconductor wafer 700. Wafer 700 may be a silicon wafer, a gallium arsenide wafer, or other wafer type. As shown in FIG. 7, wafer 700 has a surface 704 defined by a plurality of integrated circuit regions 702 (shown as small rectangles in FIG. 7). One or more of integrated circuit region 702 may be packaged into a separate IC package according to the process of flowchart 400. Any number of integrated circuit regions 702 may be included in wafer 700, including 10s, 100s, 1000s, and even larger numbers.

Wafer 700 may optionally be thinned by backgrinding. For instance, a backgrinding process may be performed on wafer 700 to reduce a thickness of wafer 700 to a desired amount, if desired and/or necessary. However, thinning of wafer 700 does not necessarily need to be performed in all embodiments. Wafer 700 may be thinned in any manner, as would be known to persons skilled in the relevant art(s). Wafer 700 may be made as thin as possible to aid in minimizing a thickness of resulting packages that will include integrated circuit regions 702. Furthermore, each integrated circuit region 702 may be tested in wafer 700. For example, test probes may be applied to terminals 320 (not shown in FIG. 7) in wafer 700 to provide test input signals and to receive test result signals, to test each integrated circuit region 702.

Wafer 700 may be singulated/diced in any appropriate manner to physically separate the integrated circuit regions from each other, as would be known to persons skilled in the relevant art(s). For example wafer 700 may be singulated by a saw, router, laser, etc., in a conventional or other fashion. Singulation of wafer 700 may result in 10s, 100s, 1000s, or even larger numbers of dies 106 (of FIG. 3), corresponding to the number of integrated circuit regions 702 of wafer 700.

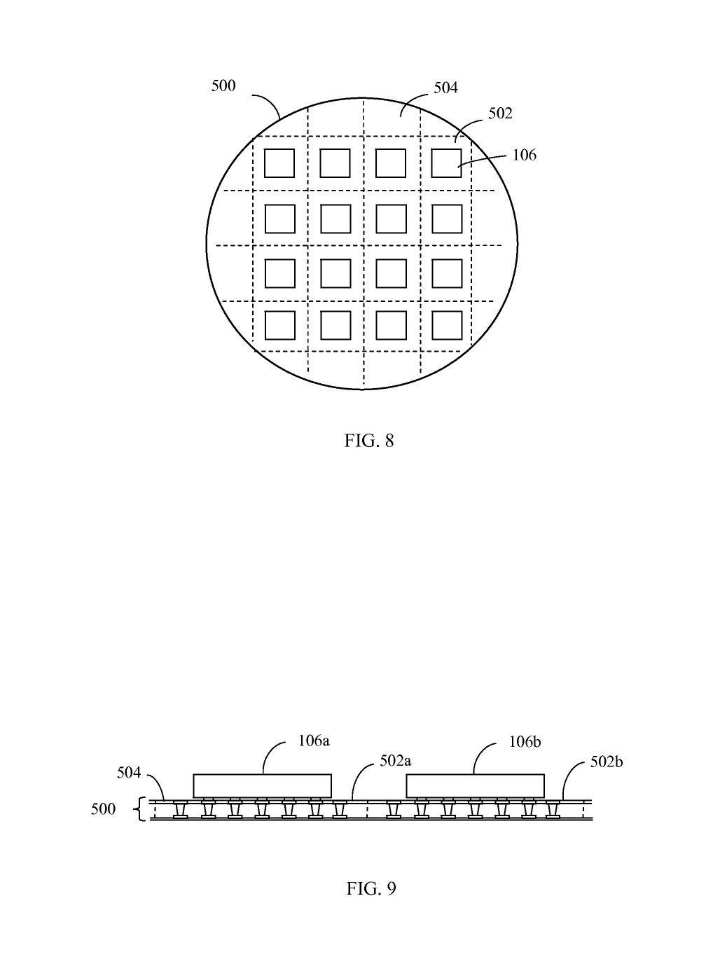

According to step 404 of FIG. 4, one or more dies singulated from a second semiconductor wafer (such as wafer 700 of FIG. 7) may be mounted to surface 504 of first semiconductor wafer 500 (FIG. 5) such that each substrate region 502 has at least one die attached thereto. For example, FIG. 8 shows a view of surface 504 of wafer 500 with dies 106 attached thereto, such that a die 106 is attached to each substrate region 502, according to an example embodiment. FIG. 9 shows a side cross-sectional view of a portion of wafer 500, with first and second dies 106a and 106b shown mounted to first and second substrate regions 502a and 502b, respectively. Dies 106 may be placed and/or positioned on substrates regions 502 in any manner, including through the use of a pick-and-place apparatus, a self-aligning process, or other technique. Terminals of dies 106 may be aligned with conductive land pads on substrate regions 502 to couple signals of dies 106 with routing of substrates regions 502. For instance, solder or other electrically conductive material (e.g., a metal or combination of metals/alloy) may be used to couple the terminals to the conductive pads. An adhesive material may be applied to the surfaces of substrate regions 502 and/or the active surfaces of dies 106 prior to placing dies 106 on substrate regions 502, and/or may be inserted between dies 106 and substrate regions 502 after the attachment (e.g., an underfill material). The adhesive material may be used to aid in adhering dies 106 to substrate regions 502. Any suitable adhesive material may be used, including a conventional die-attach material, an epoxy, an adhesive film, etc.

Furthermore, note that terminals of dies 106 include signal/die pads of the dies, and may include one or more metal layers formed on the die pads, referred to as under bump metallization (UBM) layers. UBM layers are typically one or more metal layers formed (e.g., metal deposition—plating, sputtering, etc.) to provide a robust interface between the die pads and additional routing and/or a package interconnect mechanism, such as studs or solder balls.

Referring back to FIG. 4, in step 406, the dies are encapsulated on the surface of the first semiconductor wafer. For instance, FIG. 10 shows a side cross-sectional view of the portion of wafer 500 shown in FIG. 9 with encapsulated dies, according to an example embodiment. Wafer 500 shown in FIG. 9 with encapsulated dies may be referred to as a “molded assembly” 1000. As shown in FIG. 10, dies 106a and 106b attached to substrates regions 502a and 502b are encapsulated by a molding compound 1002 applied to surface 504 of wafer 500. Molding compound 1002 is an example of an encapsulating material that may be used to encapsulate dies 106 on wafer 500. Molding compound 1002 may be applied to wafer 500 in any manner, including according to a vacuum molding process, etc. For instance, in an embodiment, a mold made be positioned over surface 504 of wafer 500 (with dies 106 attached), and molding compound 1002 may be inserted into the mold (e.g., in liquid form) and solidified to encapsulate dies 106 on wafer 500. Suitable encapsulating materials, such as molding compounds, are known to persons skilled in the relevant art(s), including resins, epoxies, etc.

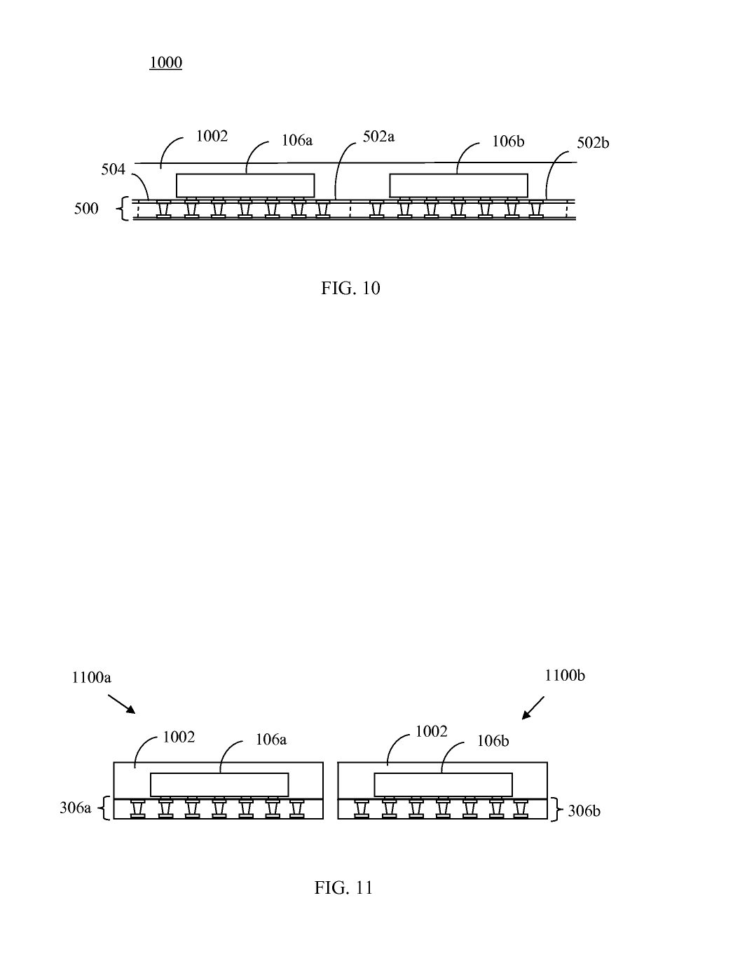

Referring back to FIG. 4, in step 408, the first semiconductor wafer is singulated to separate the plurality of substrate regions to form a plurality of integrated circuit packages, each integrated circuit package including at least one of the dies. For instance, FIG. 11 shows a first IC package 1100a and a second IC package 1100b singulated from molded assembly 1000 of FIG. 10, according to an example embodiment. Any number of IC packages 1100 may be singulated from a molded assembly, including 10s, 100s, or even thousands of IC packages 1100. As shown in FIG. 11, IC package 1100a includes die 106a mounted to substrate 306a, and molding compound 1002 that encapsulates die 106a on substrate 306a. Furthermore, IC package 1100b includes die 106b mounted to substrate 306b, and molding compound 1002 that encapsulates die 106b on substrate 306b. Substrate 306a is formed by singulating substrate region 502a from wafer 500, and substrate 306b is formed by singulating substrate region 502b from wafer 500.

IC packages 1100 may be singulated from molded assembly 1000 in any appropriate manner to physically separate them from each other, as would be known to persons skilled in the relevant art(s). For instance, IC packages 1100 may be singulated by a saw, router, laser, etc., in a conventional or other fashion. IC packages 1100a and 1100b of FIG. 11 may be singulated from molded assembly 1000 by cutting through molding compound 1002 to separate IC packages 1100a and 1100b from each other and from other IC packages 1100 (not shown in FIG. 10).

### B. Embodiments for Forming Packages Using a Carrier

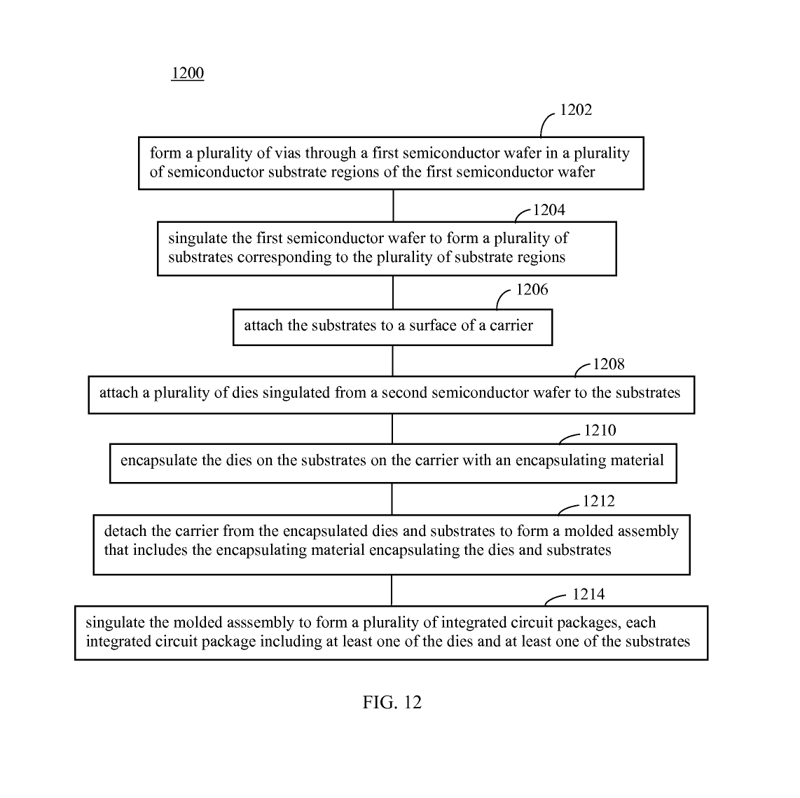

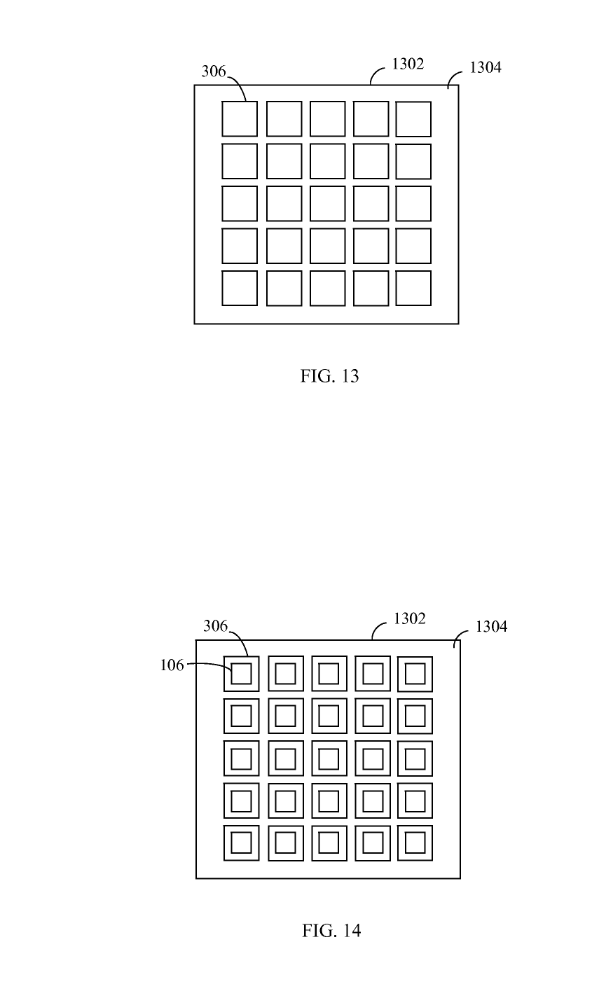

Integrated circuit packages that include a semiconductor interposer substrate, such as package 300 of FIG. 3, may be formed in various ways using a carrier. For instance, FIG. 12 shows a flowchart 1200 providing an example process for assembling integrated circuit packages, according to an embodiment. Flowchart 1200 is described with respect to FIGS. 13-18 for purposes of illustration. Other structural and operational embodiments will be apparent to persons skilled in the relevant art(s) based on the discussion provided herein. Flowchart 1200 is described as follows.

Referring to flowchart 1200, in step 1202, a plurality of vias is formed through a first semiconductor wafer in a plurality of semiconductor substrate regions of the first semiconductor wafer. For instance, as described above with respect to FIG. 5, a plurality of vias may be formed through wafer 500 in each of regions 502, similar to vias 310 shown in FIG. 3. Furthermore, similarly to the description provided above, an optional step 602 shown in FIG. 6 may be performed in flowchart 1200 to test substrate regions 502 in wafer 500 to determine a set of working substrates.

In step 1204, the first semiconductor wafer is singulated to form a plurality of substrates corresponding to the plurality of substrate regions. For instance, referring to FIG. 5, wafer 500 may be singulated/diced in any appropriate manner to physically separate substrate regions 502 from each other to form a plurality of separate substrates, as would be known to persons skilled in the relevant art(s). For example wafer 500 may be singulated by a saw, router, laser, etc., in a conventional or other fashion. Singulation of wafer 500 may result in 10s, 100s, 1000s, or even larger numbers of substrates 306 (of FIG. 3), corresponding to the number of substrate regions 502 of wafer 500.

Referring back to FIG. 12, in step 1206, the substrates are attached to a surface of a carrier. In an embodiment, substrates, such as substrates 306 singulated from wafer 500 as described above, are attached to the surface of a carrier. In an embodiment, a subset of the substrates singulated from wafer 500 that passed testing (e.g., working substrates, as described above) are attached to the carrier. Substrates that did not pass testing (e.g., the non-working substrates) are not attached to the carrier.

For instance, FIG. 13 shows a view of carrier 1302 having a planar surface 1304 with a plurality of substrates 306 attached thereto, according to an example embodiment. Substrates 306 may be placed and/or positioned on surface 1304 of carrier 1302 in any manner, including through the use of a pick-and-place apparatus, a self-aligning process, or other technique. An adhesive material may be applied to surface 1304 and/or to surfaces of substrates 306 prior to placing substrates 306 on surface 1304 to adhere substrates 306 to surface 1304. Any suitable adhesive material may be used, including an epoxy, an adhesive film, etc.

In the example of FIG. 13, twenty-five substrates 306 are shown attached to surface 1304 of carrier 1302. However, in embodiments, any number of substrates 306 may be attached to the surface of a carrier, including tens, hundreds, or even thousands of substrates 306. In one embodiment, substrates 306 may be positioned adjacent to each other (e.g., in contact with each other) on surface 1304 of carrier 1302. In another embodiment, substrates 306 may be positioned spaced apart on surface 1304 of carrier 1302, such as is shown in FIG. 13. Substrates 306 may be spaced apart by any distance, as determined for a particular application.

Any suitable type of carrier may be used for receiving the separated substrates, including a carrier made of a ceramic, a glass, a plastic, a semiconductor material (e.g., silicon, gallium arsenide, etc.), a metal, or other material. The carrier may have a planar surface for receiving substrates 306. Such carrier may have any outline shape, including being round, rectangular, or other shape. For instance, FIG. 13 shows carrier 1302 having a rectangular (e.g., square) shape. In an embodiment, carrier 1302 may be a semiconductor wafer (e.g., silicon or gallium arsenide), or may be made of another material such as plastic, ceramic, glass, a metal, etc.

Referring back to FIG. 12, in step 1208, a plurality of dies singulated from a second semiconductor wafer is attached to the substrates. For instance, as described above, FIG. 7 shows a plan view of second semiconductor wafer 700. Wafer 700 may optionally be thinned by backgrinding, and each integrated circuit region 702 of wafer 700 may optionally be tested in wafer 700. As described above, wafer 700 may be singulated/diced in any appropriate manner to physically separate the integrated circuit regions from each other, to form separate dies.

FIG. 14 shows a view of surface 1304 of carrier 1302 with substrates 306 attached thereto, and an IC die 106 attached to each substrate 306, according to an example embodiment. Dies 106 may be placed and/or positioned on substrates 306 in any manner, including through the use of a pick-and-place apparatus, a self-aligning process, or other technique. Terminals of dies 106 may be aligned with conductive land pads on substrates 306 to couple signals of dies 106 with routing of substrates 306. For instance, solder or other electrically conductive material (e.g., a metal or combination of metals/alloy) may be used to couple the terminals to the conductive pads. An adhesive material may be applied to the surfaces of substrates 306 and/or the non-active surfaces of dies 106 prior to placing dies 106 on substrates 306, and/or may be inserted between dies 106 and substrates 306 after the attachment (e.g., an underfill material). The adhesive material may be used to aid in adhering dies 106 to substrates 306. Any suitable adhesive material may be used, including a conventional die-attach material, an epoxy, an adhesive film, etc.

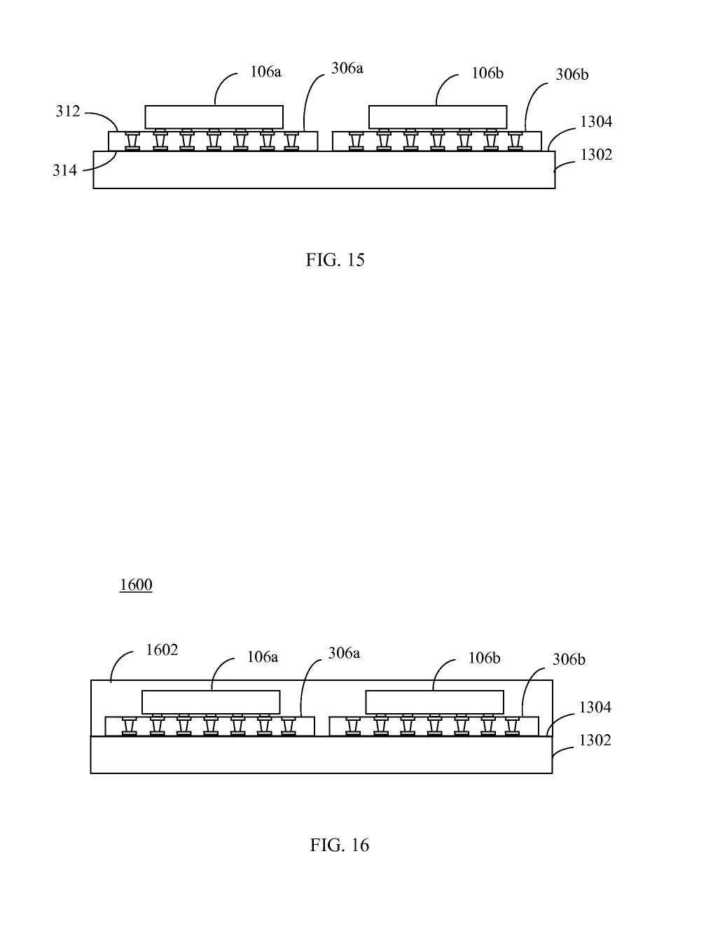

For example, FIG. 15 shows a cross-sectional view of a portion of carrier 1302, according to an embodiment. As shown in FIG. 15, substrates 306a and 306b are attached to surface 1304 of carrier 1302. As shown in FIG. 3, substrates 306a and 306b each have opposing first and second surfaces 312 and 314, with second surfaces 314 being attached to surface 1304 of carrier 1302. Die 106a is attached to first surface 312 of substrate 306a, and die 106b is attached to first surface 312 of substrate 306b. As described herein, dies 106 may be attached to substrates 306 using electrically conductive plating, studs, or bumps as signal interconnects between each die 106 and substrate 306. Furthermore, as described above, terminals of dies 106 include signal pads of the dies 106, and may include one or more metal layers formed on the die pads, referred to as UBM layers.

Furthermore, note that terminals of dies 106 include signal/die pads of the dies, and may include one or more metal layers formed on the die pads, referred to as under bump metallization (UBM) layers. UBM layers are typically one or more metal layers formed (e.g., metal deposition—plating, sputtering, etc.) to provide a robust interface between the die pads and additional routing and/or a package interconnect mechanism, such as studs or solder balls.

Referring back to FIG. 12, in step 1210, the dies are encapsulated on the carrier with an encapsulating material. For instance, FIG. 16 shows a side cross-sectional view of carrier 1302 having encapsulated dies and substrates, according to an example embodiment. As shown in FIG. 16, substrates 306a and 306b are attached to surface 1304 of carrier 1302, and dies 106a and 106b are attached to substrates 306a and 306b. Furthermore, a molding compound 1602 encapsulates substrates 306a and 306b and dies 106a and 106b on carrier 1302. Molding compound 1602 is an example of an encapsulating material that may be used to encapsulate substrates 306a and 306b and dies 106a and 106b on carrier 1302. Molding compound 1602 may be applied to carrier 1302 in any manner, including according to a vacuum molding process, etc. For instance, in an embodiment, a mold made be positioned over surface 1304 of carrier 1302 (with substrates and dies attached), and molding compound 1602 may be inserted into the mold (e.g., in liquid form) and solidified to encapsulate substrates 306 and dies 106 on carrier 1302. Suitable encapsulating materials, including molding compounds, are known to persons skilled in the relevant art(s), including resins, epoxies, etc.

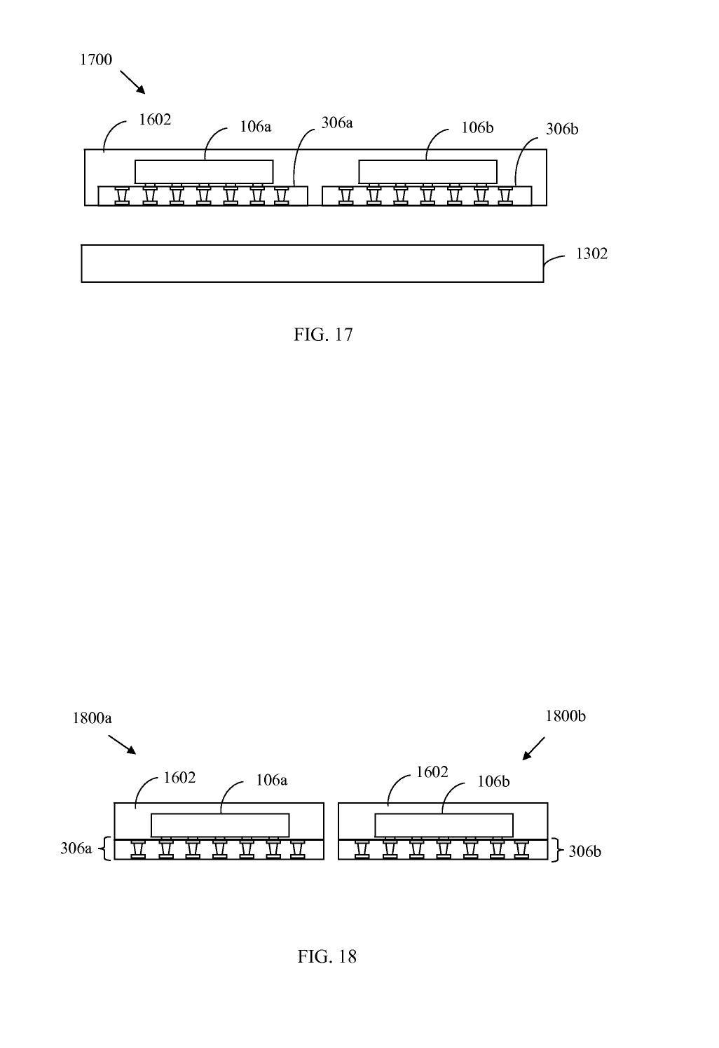

In step 1212, the carrier is detached from the encapsulated dies and substrates to form a molded assembly that includes the encapsulating material encapsulating the dies and substrates. For example, FIG. 17 shows a side cross-sectional view of carrier 1302 having been removed or demounted from the encapsulated dies and substrates, according to an example embodiment. In FIG. 17, substrates 306a and 306b, dies 106a and 106b, and molding compound 1602 form a molded assembly 1702 that is detached from carrier 1302. Bottom surfaces of substrates 306a and 306b are flush with and exposed at a surface of molded assembly 1702 (a bottom surface in FIG. 17). Otherwise, dies 106a and 106b and substrates 306a and 306b are encapsulated by molding compound 1602 in molded assembly 1702. Carrier 1302 may be detached from molded assembly 1702 in any manner. For instance, molded assembly 1702 may be peeled from carrier 1302, molded assembly 1702 and/or carrier 1302 may be heated or cooled to cause or enable carrier 1302 to detach from molded assembly 1702, etc. In an embodiment, molding compound 1602 may adhere to substrates 306a and 306b more strongly than does carrier 1302 (e.g., more strongly than the adhesive material attaching substrates 306a and 306b to carrier 1302), to enable substrates 306a and 306b to be detached from carrier 1302 along with molding compound 1602, rather than substrates 306a and 306b remaining on carrier 1302 after the detaching.

Referring back to FIG. 12, in step 1212, the molded assembly is singulated to form a plurality of integrated circuit packages, each integrated circuit package including at least one of the dies and at least one of the substrates. For example, FIG. 18 shows a first IC package 1800a and a second IC package 1800b singulated from molded assembly 1700 of FIG. 17, according to an embodiment. Any number of IC packages 1800 may be singulated from a molded assembly, including 10s, 100s, or even thousands of IC packages 1800. As shown in FIG. 18, IC package 1800a includes die 106a mounted to substrate 306a, and molding compound 1702 that encapsulates die 106a on substrate 306a. Furthermore, IC package 1800b includes die 106b mounted to substrate 306b, and molding compound 1702 that encapsulates die 106b on substrate 306b.

IC packages 1800 may be singulated from molded assembly 1700 in any appropriate manner to physically separate them from each other, as would be known to persons skilled in the relevant art(s). For instance, IC packages 1800 may be singulated by a saw, router, laser, etc., in a conventional or other fashion. IC packages 1800a and 1800b of FIG. 18 may be singulated from molded assembly 1700 by cutting through molding compound 1602 to separate IC packages 1800a and 1800b from each other and from other IC packages 1800 (not shown in FIG. 17). In one embodiment, the sawing may be performed directly adjacent to the perimeter edges of substrates 306 so that molding compound 1702 is not present around the perimeter edges of substrates 306a and 306b in IC packages 1800a and 1800b (i.e., the perimeter substrate edges are exposed, as shown in FIG. 18). Alternatively, the sawing may be performed a distance from the perimeter edges of substrates 306a and 306b so that some molding compound 1702 remains present to cover the perimeter edges of substrates 306a and 306b in IC packages 1800a and 1800b (the perimeter substrate edges are not exposed).

### C. Example Package Embodiments

As described above, IC packages, such as package 300 (FIG. 3), packages 1100a and 1100b (FIG. 11), and packages 1800a and 1800b (FIG. 18), may be formed in various ways, according to embodiments. Such packages include semiconductor substrates, such as substrate 306, that include through vias and routing to couple signals of mounted dies to package interconnects. Such vias and routing may be configured in any manner, including any numbers of vias and any number of routing layers.

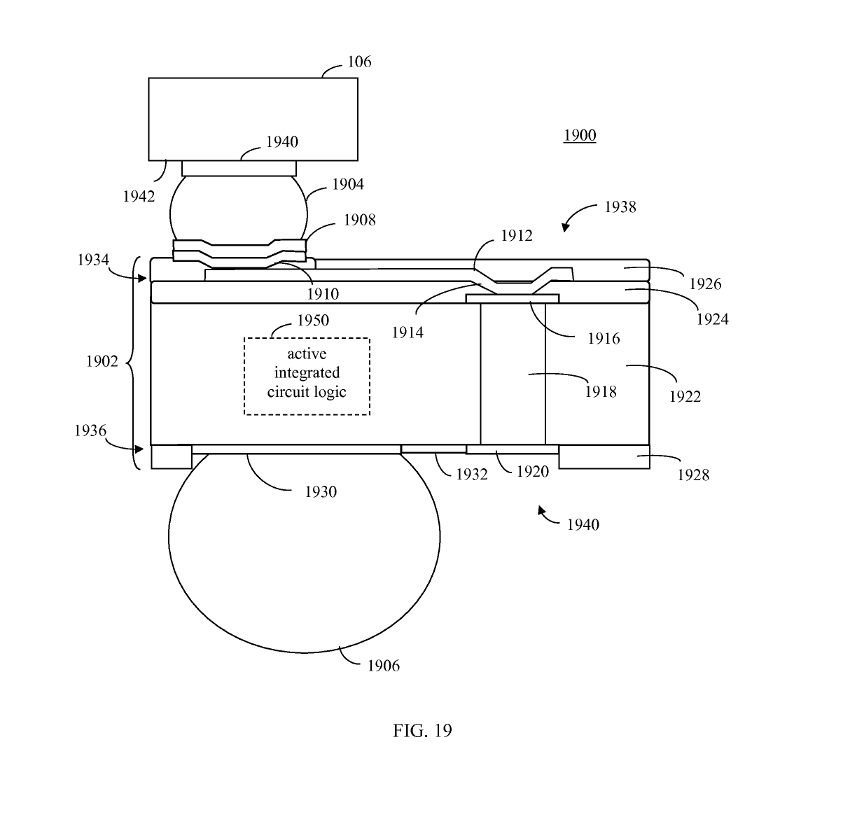

For instance, FIG. 19 shows a side cross-sectional view of a portion of an IC package 1900, according to an example embodiment. Package 1900 is shown to illustrate examples of routing, which may be modified in various ways, as would be known to persons skilled in the relevant art(s) from the teachings herein. As shown in FIG. 19, package 1900 includes die 106, a semiconductor substrate 1902, a solder bump 1904, and a ball interconnect 1906. Solder bump 1904 is present to mount a terminal 1940 of die 106 to substrate 1902. Ball interconnect 1906 is present to attach substrate 1902 to a circuit board (not shown in FIG. 19). Any number of solder bumps 1904 and/or ball interconnects 1904 may be present in embodiments. Package 1900 is further described as follows.

As shown in FIG. 19, routing is formed on a first surface 1938 of substrate 1902 to route a signal from solder bump 1904 to a via 1918 through substrate 1902. For example, as shown in FIG. 19, substrate 1902 includes a core semiconductor layer 1922, a first insulating layer 1924 formed on core semiconductor layer 1922 at first surface 1938, a first routing layer 1934 formed on first insulating layer 1924, and a second insulating layer 1926 formed on routing layer 1934. Via 1918 is a through via that passes completely through core semiconductor layer 1922. Via 1918 has a first via pad 1916 at a first surface of core semiconductor layer 1922, and a second via pad 1920 at a second surface of core semiconductor layer 1922. A trace 1912 is formed in routing layer 1934 that is connected to via pad 1916 through an opening in first insulating layer 1924 at a first end of trace 1912. Trace 1912 may also be referred to as a redistribution layer or redistribution interconnect. A land pad 1908 is formed on trace 1912 through an opening 1910 in second insulating layer 1926 near or at a second end of trace 1912. Solder bump 1904 is attached to land pad 1908. Land pad 1908 may include multiple layers of electrically conductive material. For instance, land pad 1908 may be a UBM layer that includes one or more metal layers formed (e.g., metal deposition—plating, sputtering, etc.) to provide a robust interface between terminals 1940 and additional routing and/or a package interconnect mechanism, such as studs or solder balls. The metal layers may be formed of different metals and/or alloys to enable solder bump 1904, which may include a first metal/alloy, to adhere to trace 1912, which may be made of a second, different metal/alloy.

As shown in FIG. 19, trace 1912 is fanout routing provided by substrate 1902 for die 106. This is because trace 1912 extends over substrate 1902 outside of an area of the active surface of die 106 facing substrate 1902 (surface 1942 of die 106). In other words, trace 1912 extends outside of an area between die 106 and substrate 1902 over first surface 1938 of substrate 1902. As such, trace 1912 fans-out from die 106, with substrate 1902 provide a larger surface area than the area of die 106 for signals at terminals of die 106 to be routed over by corresponding traces, enabling package 1900 to be more easily mounted to a circuit board (with larger land pad spacing enabled). As shown in FIG. 19, solder ball 1906 underneath die 106 extends partially outside of the area of die 106 (to the right side in FIG. 19). In another embodiment, solder ball 1906 may be located entirely outside of the area of die 106 (e.g., further to the right in FIG. 19).

As shown in FIG. 19, routing is formed on a second surface 1940 of substrate 1902 to route the signal from via 1918 to solder ball 1906. For example, as shown in FIG. 19, substrate 1902 includes a second routing layer 1936 formed on core semiconductor layer 1922 at second surface 1940, and a third insulating layer 1928 formed on routing layer 1936. Routing layer 1936 includes via pad 1920 of via 1918, a trace 1932, and a solder ball pad 1930. Trace 1932 connects via pad 920 and solder ball pad 1930. Via pad 1920, trace 1932, and solder ball pad 1930 are exposed through openings in third insulating layer 1928. Interconnect ball 1906 is formed on solder ball pad 1930. As such, an electrical connection is formed through semiconductor substrate 1902 from solder bump 1904, through land pad 1908, trace 1912, via pad 1916, via 1918, via pad 1920, trace 1932, solder ball pad 1930, to interconnect ball 1906. The electrical connection electrically couples of signal of terminal 1940 of die 106 to a land pad on a circuit board to which package 1900 is mounted. Any number of electrical connections may be formed through substrate 1902 in a similar manner.

Note that although a signal routing layer 1934 is shown at first surface 1938 of substrate 1902, and single routing layer 1936 is shown at second surface 1940 of substrate 1902, any number of additional routing layers may be present at either or both of surfaces 1938 and 1940 to route signals through substrate 1902 to solder bump 1904 and/or solder ball 1906. Furthermore, in embodiments, interconnect ball 1906 may be formed directly on via pad 1920 and/or solder bump 1904 may be formed directly on via pad 1916. In embodiments, solder bump 1904 and/or interconnect ball 1906 may or may not be present to form various package types.

For instance, FIGS. 3 and 20-22 show examples of IC packages that include a semiconductor interposer substrate, according to embodiments. Package 300 of FIG. 3 described above is an example of a land grid array (LGA) package. An LGA package, such as package 300, is a type of surface-mount package for integrated circuits (ICs) that has an array of pads used to mount the package to a circuit board. An LGA package can be electrically connected to a printed circuit board (PCB) either by the use of a socket (having pins) or by soldering the pads directly to the board.

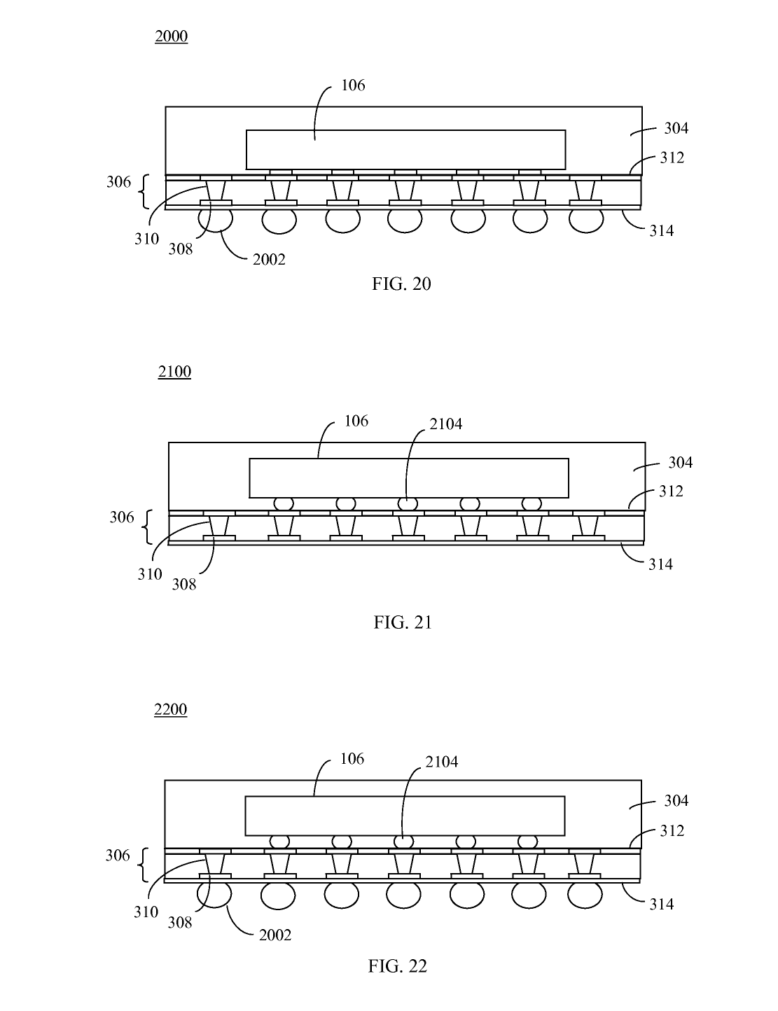

FIG. 20 shows a side cross sectional view of a ball grid array (BGA) package 2000. BGA package 2000 is similar to package 300 of FIG. 3, with the addition of an array of solder balls 2002 attached to solder ball pads at second surface 314 of substrate 306. Solder balls 2002 may be reflowed to attach BGA package 2000 to a circuit board. Solder balls 2002 may be attached to substrate 306 when in-wafer (e.g., to wafer 500 in an additional process of flowchart 400), or after substrate 306 is separated from the wafer.

FIG. 21 shows a side cross sectional view of another LGA package 2100. LGA package 2100 is a type of LGA package similar to LGA package 300 of FIG. 3, with the addition of an array of solder bumps 2104 attached to terminals of die 106 to mount die 106 to land pads on first surface 312 of substrate 306. LGA package 2100 of FIG. 21 may be referred to as a flip chip LGA package.

FIG. 22 shows a side cross sectional view of a ball grid array (BGA) package 2200. BGA package 2200 is a type of BGA package similar to BGA package 2000 of FIG. 20, with the addition of array of solder bumps 2104 attached to terminals of die 106 to mount die 106 to land pads on first surface 312 of substrate 306. BGA package 2200 of FIG. 22 may be referred to as a flip chip BGA package.

In embodiments, various forms of interconnects may be formed on second surface 314 of substrate 306 to attach packages to circuit boards. Examples of such interconnects include ball interconnects (e.g., solder balls 2002) for BGA packages, pins (e.g., for pin grid array packages (PGAs)), posts, or other types of interconnects. Such interconnects may be applied to substrates in any manner, including according to conventional and proprietary techniques.

Note that in embodiments, the semiconductor substrates included in the IC packages (e.g., package 300, packages 1100a and 1100b, packages 1800a and 1800b, etc.) may be active or passive. For instance, FIG. 19 shows substrate 1902 optionally including active integrated circuit logic 1950. When present, active integrated circuit logic 1950 makes substrate 1902 an active semiconductor substrate. When not present, substrate 1902 is a passive semiconductor substrate. Logic 1950 may include any form of logic (e.g., in the form of transistors, logic gates, etc.), such as processing logic, configured to perform any logic function. Logic 1950 may be coupled to vias and/or routing in substrate 1902 to be electrically coupled to signals of die 106.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A method, comprising:
forming a plurality of vias through a first semiconductor wafer in a plurality of semiconductor substrate regions of the first semiconductor wafer;
attaching a plurality of dies singulated from a second semiconductor wafer to a surface of the first semiconductor wafer;
encapsulating the dies on the surface of the first semiconductor wafer; and
singulating the first semiconductor wafer to separate the plurality of substrate regions to form a plurality of integrated circuit packages, each integrated circuit package including at least one of the dies and a substrate corresponding to a substrate region, each substrate including fanout routing.

2. The method of claim 1, wherein the first semiconductor wafer is a silicon wafer and the vias are through-silicon vias.

3. The method of claim 1, further comprising:
testing the substrate regions in the first semiconductor wafer to determine a set of working substrate regions prior to said singulating.

4. The method of claim 1, further comprising:
forming routing on a surface of the first semiconductor wafer in each of the semiconductor regions.

5. The method of claim 1, wherein said attaching comprises:
mounting each die to a substrate region using an array of solder bumps.

6. The method of claim 1, further comprising:
forming a plurality of interconnect balls on a second surface of the first semiconductor wafer prior to said singulating;
wherein each integrated circuit package includes interconnect balls of the plurality of interconnect balls that are used to interface the integrated circuit package with a circuit board.

7. The method of claim 1, wherein an array of electrically conductive pads on a surface of each integrated circuit package is used to interface the integrated circuit package with a circuit board as a land grid array package.

8. A method, comprising:
forming a plurality of vias through a first semiconductor wafer in a plurality of semiconductor substrate regions of the first semiconductor wafer;
singulating the first semiconductor wafer to form a plurality of substrates corresponding to the plurality of substrate regions;
attaching the substrates to a surface of a carrier;
attaching a plurality of dies singulated from a second semiconductor wafer the substrates;
encapsulating the dies on the substrates on the carrier with an encapsulating material;
detaching the carrier from the encapsulated dies and substrates to form a molded assembly that includes the encapsulating material encapsulating the dies and substrates; and
singulating the molded assembly to form a plurality of integrated circuit packages, each integrated circuit package including at least one of the dies and at least one of the substrates, each substrate including fanout routing.

9. The method of claim 8, wherein the first semiconductor wafer is a silicon wafer and the vias are through-silicon vias.

10. The method of claim 8, further comprising:
testing the substrate regions in the first semiconductor wafer to determine a set of working substrate regions prior to said singulating the first semiconductor wafer.

11. The method of claim 8, further comprising:
forming routing on a surface of the first semiconductor wafer in each of the semiconductor regions.

12. The method of claim 8, wherein said attaching comprises:
mounting each die to a substrate using an array of solder bumps.

13. The method of claim 8, further comprising:
forming a plurality of interconnect balls on a second surface of the first semiconductor wafer prior to said singulating the first semiconductor wafer;
wherein each integrated circuit package includes interconnect balls of the plurality of interconnect balls that are used to interface the integrated circuit package with a circuit board.

14. The method of claim 8, wherein an array of electrically conductive pads on a surface of each integrated circuit package is used to interface the integrated circuit package with a circuit board as a land grid array package.

15. An integrated circuit package, comprising:
a silicon substrate that has opposing first and second surfaces, a plurality of vias through the silicon substrate, and routing on at least the first surface of the silicon substrate;
a die mounted to the first surface of the silicon substrate; and
an encapsulating material that encapsulates the die on the first surface of the silicon substrate.

16. The package of claim 15, further comprising:
a plurality of solder bumps that attach the die to the first surface of the silicon substrate.

17. The package of claim 15, further comprising:
a plurality of interconnect balls attached to the second surface of the silicon substrate.

18. The package of claim 15, further comprising:
an array of electrically conductive pads on the second surface of the silicon substrate that is used to interface the integrated circuit package with a circuit board as a land grid array package.

19. The package of claim 15, wherein the vias are through-silicon vias.

20. The package of claim 15, wherein the silicon substrate includes active integrated circuit logic.
